(19) United States
(12) Patent Application Publication
(10) Pub. No.: US 2022/0198077 A1
(43) Pub. Date: Jun. 23, 2022

(54) INTERACTIVE GRAPHICS TOOL FOR CONVEYING MANUFACTURABILITY FEEDBACK IN 3D GRAPHICS VIEWERS

(71) Applicant: Fictiv, Inc., San Francisco, CA (US)

(72) Inventors: Jeronimo Mora, Concord, CA (US); Gregory Burton, Mountain View, CA (US)

(21) Appl. No.: 17/554,420

(22) Filed: Dec. 17, 2021

Related U.S. Application Data
(60) Provisional application No. 63/126,957, filed on Dec. 17, 2020.

(51) Int. Cl. G06F 30/10; G06Q 50/04

(52) U.S. Cl. CPC G06F 30/10; G06Q 50/04

(57) ABSTRACT

A design analysis system includes a graphics viewer that renders computer-aided design (CAD) models of objects and enables annotation and review of the rendered object within the context of the graphics viewer. A first annotation from a set of annotations is displayed in the graphics viewer by displaying annotation data and rendering the object in the graphics viewer according to viewer state data captured at the time the first annotation was created. A second annotation from the set of annotations is then displayed by the graphics viewer displaying corresponding annotation data and modifying the rendering of the object according to viewer state data captured at the time the second annotation was created. Based on the CAD model and the annotations, instructions for manufacturing the object are generated.

### CROSS-REFERENCE TO RELATED APPLICATION

This application claims the benefit of U.S. Provisional Application No. 63/126,957, filed Dec. 17, 2020, which is incorporated herein by reference in its entirety.

### BACKGROUND

Physical products are often designed with particular specifications. For example, a mechanical device may include a design with specific dimensions so that the mechanical device functions properly in a system. Designers or engineers may use drawings or depictions of the product to capture the specifications of that product. Examples of tools to capture depictions of products can include a digital document in various formats (e.g., in portable document format (PDF), a slideshow format (Microsoft PowerPoint®) or in an electronic image file (e.g., bitmap (BMP), Joint Photographic Experts Group (JPEG)). Another example tool to capture the specifications of a product can include Computer Aided Design (CAD) model files (e.g. standard triangle language (STL), standard for the exchange of product model data (STEP)) produced by various sources, such as Dassault® or Siemens®.

Many designers of physical products work with manufacturers to manufacture the physical products with the particular specifications. Examples of such manufacturers can include machine shops, contractors, contract manufacturers, etc. The manufacturer may inspect design documents (e.g., PDF document, CAD models) to evaluate manufacturability of a product before beginning the manufacturing process.

### BRIEF DESCRIPTION OF THE DRAWINGS

FIGS. 1-3 illustrate example annotations of screenshots of three-dimensional models.

FIG. 4A is a block diagram illustrating components of a design analysis system.

FIG. 4B illustrates an example process for analyzing design files.

FIGS. 5A-5E illustrate example user interfaces generated during interactive analysis of design files.

FIG. 6 is a block diagram illustrating an example of a processing system in which at least some operations described herein can be implemented.

The drawings and tables depict various embodiments for illustration only. Those skilled in the art will recognize that alternative embodiments may be employed without departing from the principles of the technology. Accordingly, while specific embodiments are shown in the drawings, the technology is amenable to various modifications.

### DETAILED DESCRIPTION

Various examples of the invention will now be described. The following description provides certain specific details for a thorough understanding and enabling description of these examples. One skilled in the relevant technology will understand, however, that the invention can be practiced without many of these details. Likewise, one skilled in the relevant technology will also understand that the invention can include many other obvious features not described in detail herein. Additionally, some well-known structures or functions may not be shown or described in detail below, to avoid unnecessarily obscuring the relevant descriptions of the various examples.

The terminology used below is to be interpreted in its broadest reasonable manner, even though it is being used in conjunction with a detailed description of certain specific examples of the invention. Indeed, certain terms may even be emphasized below; however, any terminology intended to be interpreted in any restricted manner will be overtly and specifically defined as such in this Detailed Description section.

Generally, engineers who wish to have a design or part manufactured will contact machine shops, manufacturers, and contract manufacturers. The design will contain features or areas that are either manufacturable as designed, manufacturable if modified in some way, or strictly not manufacturable. As a part of an intake and quoting process, the contract manufacturers or machine shops provide feedback to the engineer in the form of design for manufacturability (DFM) feedback, design for assembly (DFA) feedback, design for cost (DFC) feedback, design for testability (DFT) feedback, or other design analysis, which are collectively referred to herein as DFX feedback. This DFX feedback is usually conveyed to the engineer through various means, whether through direct modification of computer-aided design (CAD) files, marking up of the 2D drawing (a two-dimensional representation of the 3D model as seen from various views), or by creating slideshow-style presentations (e.g. using a software such as Microsoft PowerPoint). These presentations often include screenshots of the 3D model taken from inside CAD software; the 3D model can be orientated in various ways, perhaps with areas of interest highlighted via use of textures or selection of faces, edges, or vertices.

However, 3D viewers have limited interactivity, with typical interaction types limited to selecting faces of rendered 3D objects, capturing cross-sectional views, and manipulating camera controls to view a rendered 3D object from different angles. If a manufacturer wants to relate more complicated DFX information to an engineer, the manufacturer typically must leave the 3D graphics platform and introduce any number of external tools (CAD tools, image manipulation tools, Microsoft Powerpoint, etc.) in order to communicate DFX feedback to the customer by using slideshows.

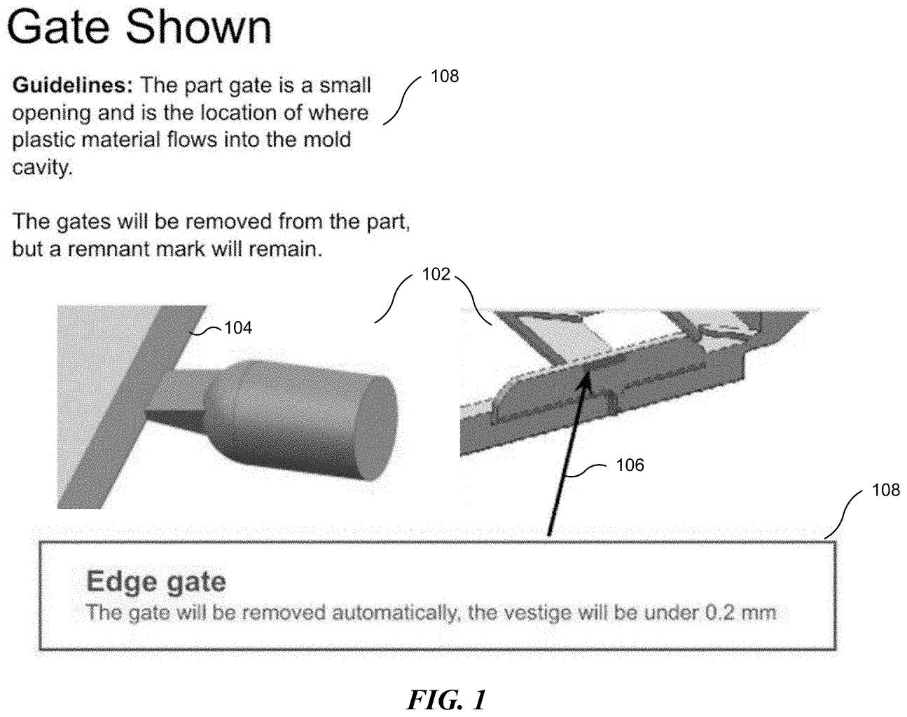

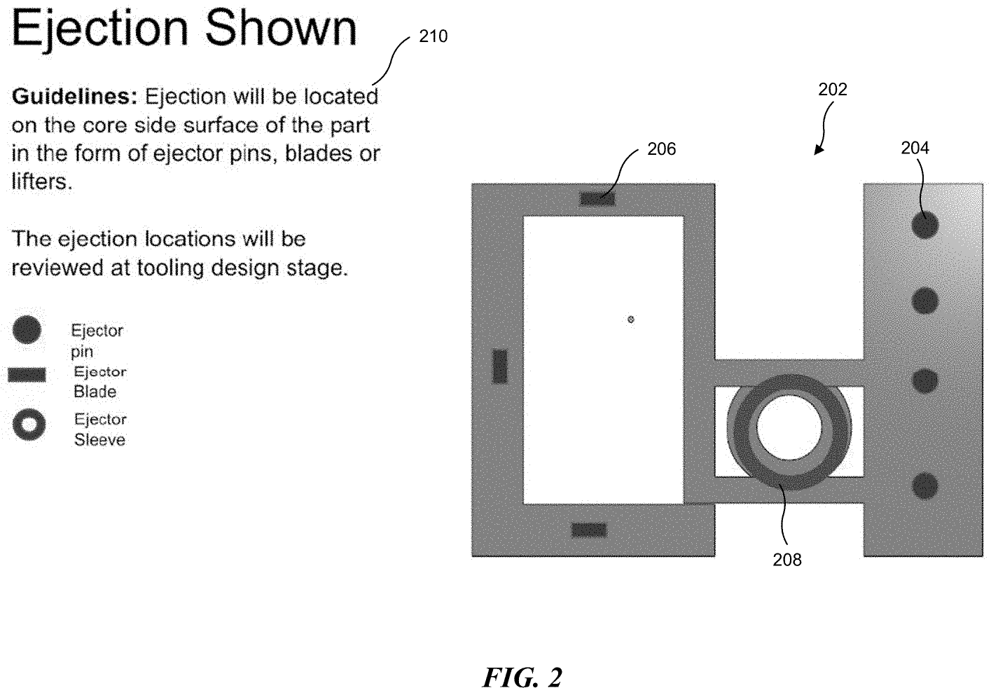

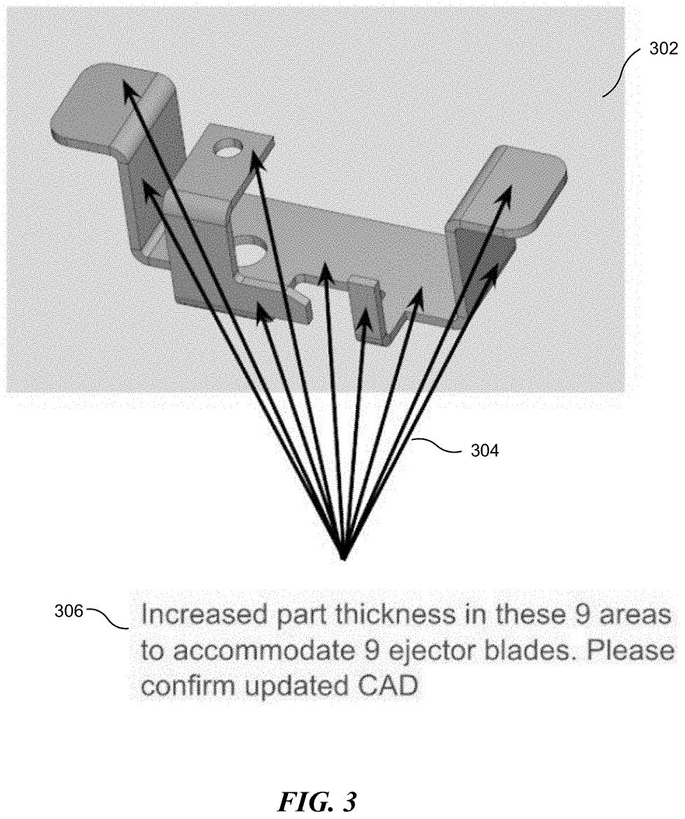

Example screenshots and associated markup are shown in FIGS. 1-3. As shown in these figures, manipulation of screenshots can include any combination of freeform annotation, drawing of predefined or custom shapes such as arrows or circles to call out areas of interest, or use of text boxes. For example, FIG. 1 shows the use of CAD screenshots, freeform annotation, an arrow graphic, and a text box to give manufacturability feedback. FIG. 2 illustrates the use of a CAD screenshot and custom graphics (a filled circle, a rectangle, and a ring) to convey manufacturability feedback. FIG. 3 illustrates a CAD screenshot annotated with arrow graphics and a text box.

The process of generating DFX feedback as shown in FIGS. 1-3 is a laborious and time-consuming process that leads to longer quoting lead times for customers and reduced manufacturer efficiency. In addition to loss of efficiency, taking screenshots, importing them into slideshow software, and then performing manipulation of the imported image can result in low quality images and products due to repeated manipulation as customers and manufacturers discuss the feedback at length. This loss of quality inevitably leads to miscommunications and customer dissatisfaction.

To solve these problems, a design analysis system according to various implementations herein includes annotation tools enabling a user to mark up a three- dimensional model within the context of a 3D viewer. The user loads a model (such as a CAD file) into the analysis system, marks up the rendered image of the 3D model within the context of the 3D viewer, and saves the state of the viewer or website in a database in association with the markup of the image. The design analysis system uses this saved state data to recreate the canvas as marked up by the user, for example enabling an administrator to show it to the customer within the viewer without loss in quality or clarity. Because the viewer is interactive, the customer can also then immediately manipulate the viewer to inspect regions of their 3D model around the areas annotated by the administrator.

### Design Analysis System

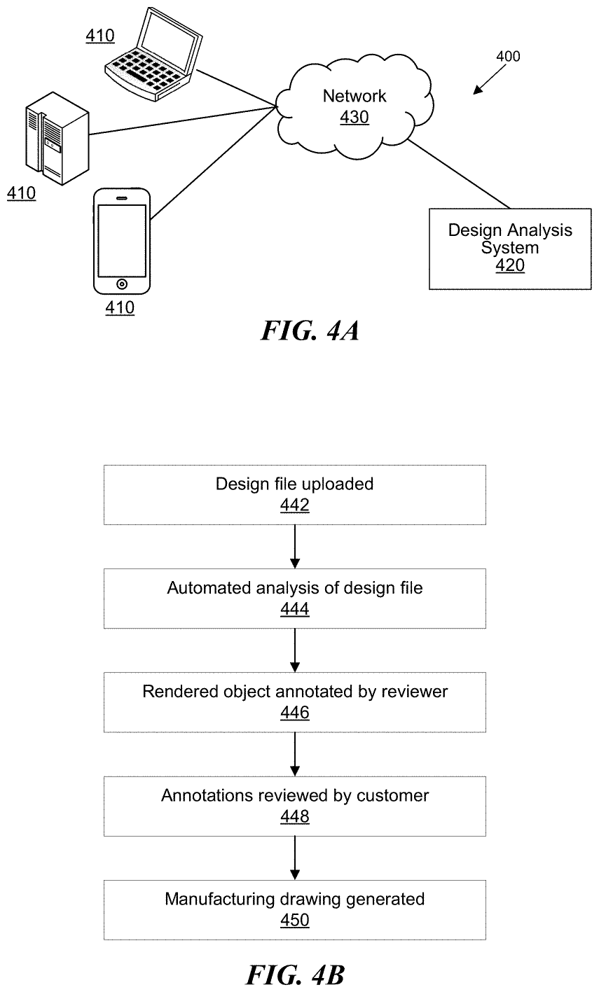

FIG. 4A is a block diagram illustrating an environment 400 in which a design analysis system 420 operates. As shown in FIG. 4A, the environment 400 can include one or more user devices 410 and the design analysis system 420, in communication over a network 430. Other implementations of the environment 400 can include additional or different devices. For example, functionality of the design analysis system 420 can be divided between multiple devices or systems.

The design analysis system 420 includes a 3D graphics viewer comprising software that is capable of rendering and displaying an interactive 3D model specified in a CAD file. The viewer displays the rendered model in a graphical user interface (e.g., a canvas) that enables a user to manipulate the rendered model, including rotating the model in three dimensions and zooming in or out. The viewer can additionally include functionality to change colors, textures, or transparencies of surfaces, edges, or vertices of a rendered model, capture cross-sections of the rendered model, or change the relative positioning of sub-components of the model. The state of the viewer—including camera rotation, camera position, camera center of orbit, camera look target, object state (such as face and edge colors, transparency, or textures), state of its annotations (such as position, textures, or types of annotations), or state of special visualizations (including additional 2D or 3D objects in scene such as a color-bar)—can be captured and stored by the design analysis system 420 at various times in order to reproduce a given viewer state. In some implementations, the 3D graphics viewer is accessible over the Internet, for example as a web application that is displayed on an electronic device of a user. Other implementations of the viewer are built into a CAD tool that, in addition to a viewer to render a 3D model, includes editing software to create and modify the 3D model.

The design analysis system 420 can further include an annotation subsystem that interacts with the 3D graphics viewer to enable annotation of rendered objects within the viewer. Some implementations of the annotation subsystem include one or more application programming interfaces (APIs) for generating and rendering graphical annotations, which are called by the 3D viewer in response to user interaction with the viewer. For example, the 3D graphics viewer can leverage libraries or APIs associated with Web Graphics Library (WebGL), such as Three.js or Two.js, to generate a freeform annotation tool usable to produce markup for display within the context of the viewer. The APIs dynamically or statically draw shapes, lines, text, or other annotations associated with the rendered model in response to inputs from a user.

Some implementations of the annotation subsystem include a web-based annotation layer displayed to overlap the canvas of the 3D viewer. The user can switch control between the canvas and the annotation layer to manipulate the rendered model and annotate the model. By way of example, the 3D viewer can include annotation layer graphics held in a transparent markup language element, displayed over another markup language element holding the canvas. Control switches between the canvas element and the annotation element as the user manipulates the model and adds or modifies annotations.

The annotation subsystem generates annotation data in response to user inputs. Such annotation data can include text as well as two-dimensional or three-dimensional shapes or objects drawn within the graphics viewer. User inputs can further customize properties of the annotations, such as colors, sizes, line widths, surface textures, or transparency. Three-dimensional entities, such as spheres, cones, or planes, can be displayed such that they move or zoom with the model if the model is manipulated within 3D space. Two-dimensional entities, such as a transparent <canvas> or <div> HTML element, can be overlaid on the 3D model.

The design analysis system 420 performs design analysis (DFX) and production parameters analysis based on models uploaded to the design analysis system 420 and user annotations to the models. The DFX analysis can include automated analysis by the design analysis system 420 (e.g., by applying a set of rules), human analysis facilitated by the design analysis system 420, or both, and is used to evaluate any of a variety of parameters related to the manufacturability of a product based on the design file that is uploaded. For example, the DFX analysis can include verifying that the design itself satisfies a set of constraints corresponding to the method of manufacturing selected by the user (such as all walls in the design having at least a specified minimum wall thickness, sufficient support structures, adequate tolerances, or the like), verifying that the material selected for the product is compatible with the selected method of manufacturing, or assessing whether the selected material will satisfy design constraints such as mechanical or thermal properties. The production parameters analysis performed by the design analysis system 420 includes a calculation of the parameters of production, based on the features of the product that are specified by the design file or modified during DFX analysis. These production parameters include, for example, the cost of materials for the product, the labor cost to manufacture the product, and the amount of time needed to manufacture the product. As part of the production parameter analysis, the design analysis system 420 can estimate manufacturing complexity (labor hours, material size, etc.), identify potential areas that might be problematic for manufacturing, and detect special requirements of the user or the design.

The user devices 410 are devices usable to interact with the design analysis system 420. The user devices 410 can each include an application that facilitates interaction with the 3D viewer and annotation subsystem, such as a browser application. Users can use the devices 410 to upload files to the design analysis system 420, annotate models, view and approve annotations, or interact with other users to perform DFX and pricing analysis of models. The user devices 410 can include any of a variety of types of devices that are capable of receiving users inputs, outputting information to a user, and communicating over a network, include desktop computers, laptop computers, tablets, mobile phones, smart televisions, or augmented or virtual reality systems.

FIG. 4B illustrates a process for analyzing design files using the design analysis system 420. As shown in FIG. 4B, a user, such as a customer, uploads a design file for an object to the design analysis system 420 at block 442. Design files can be uploaded in two- dimensional (such as .dxf) or three-dimensional (such as .step) CAD formats that include rendering instructions readable by a computer to render the object within a graphics viewer. The user can also upload one or more 2D files (such as .pdf) containing more detailed technical specifications, such as tolerances for certain dimensions, material selection, or the like, and link these files containing technical data to parts and assemblies. Once uploaded, the system automatically analyzes geometry of the part, at block 444, and generates a manufacturing quote including at least pricing and lead time to produce the part. The system retrieves various geometric and user inputs (e.g., from a database) and process them using DFX and production parameters analysis.

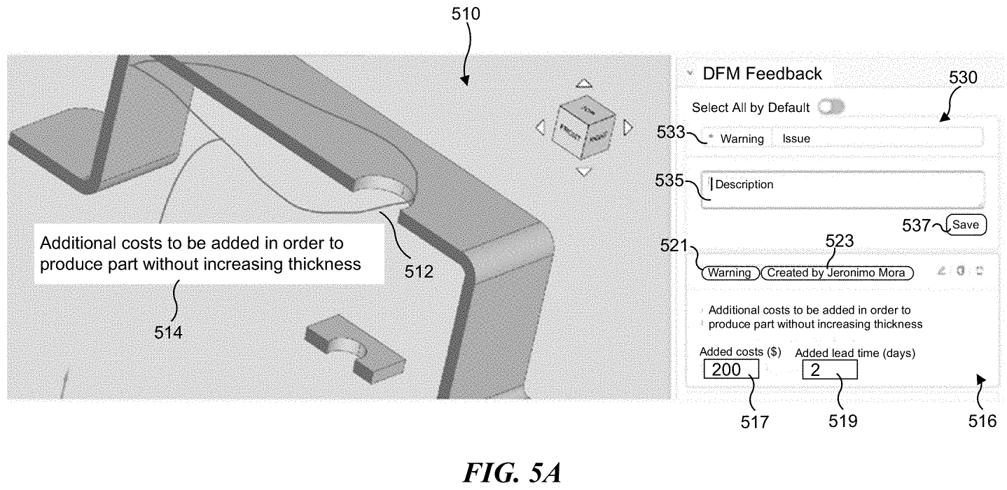

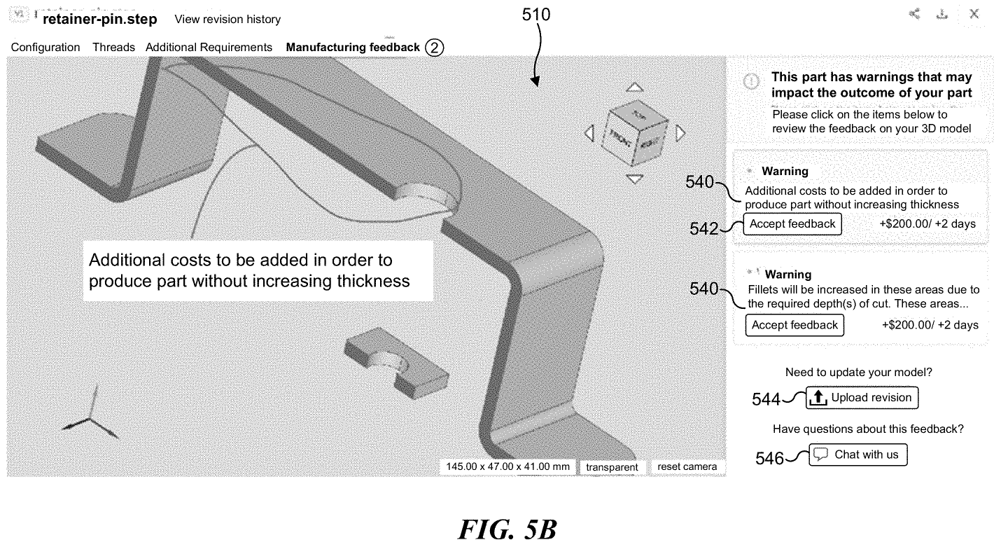

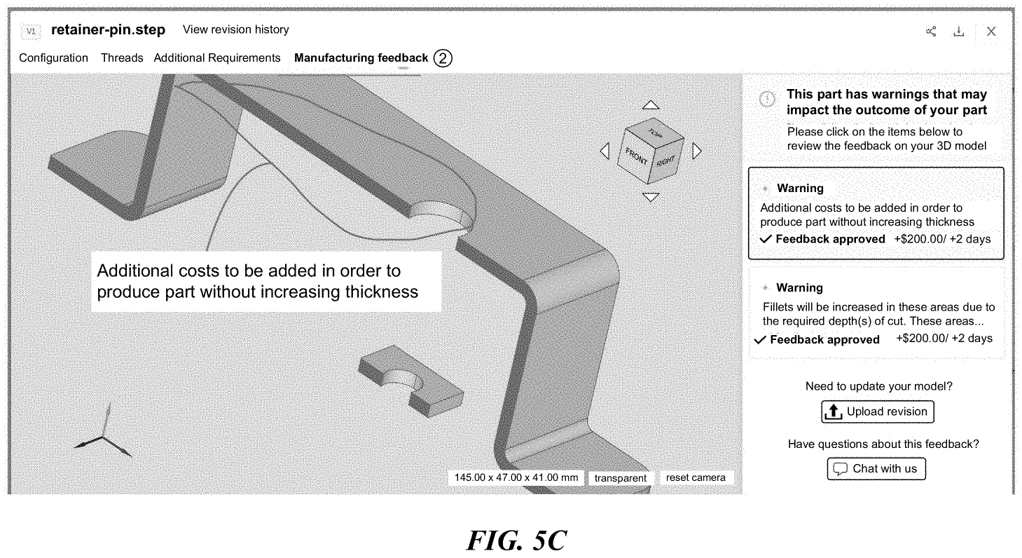

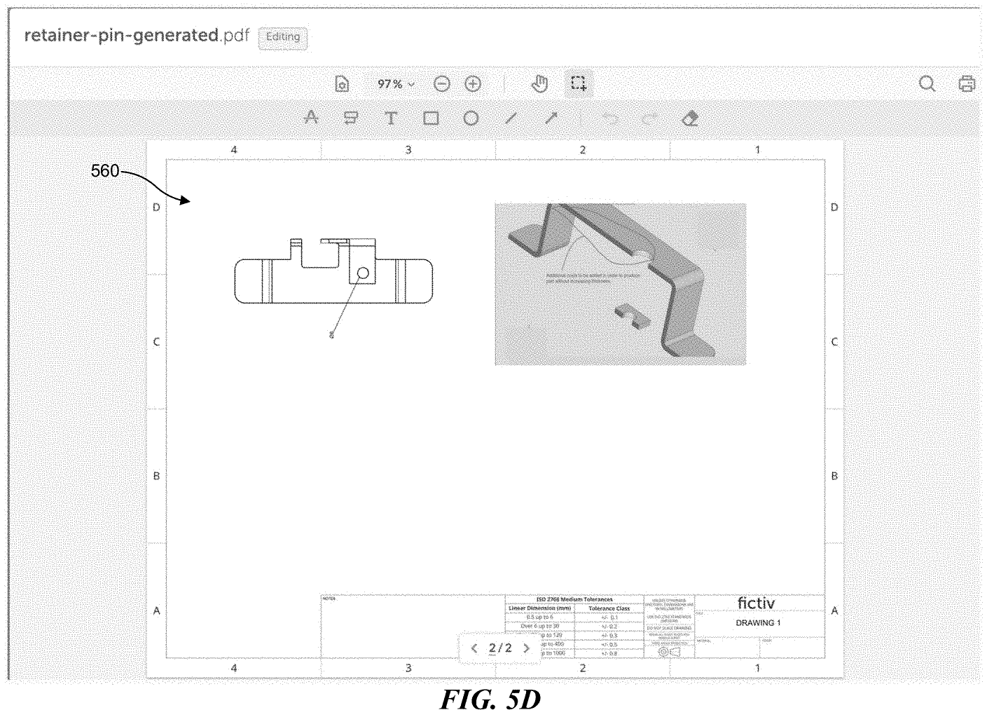

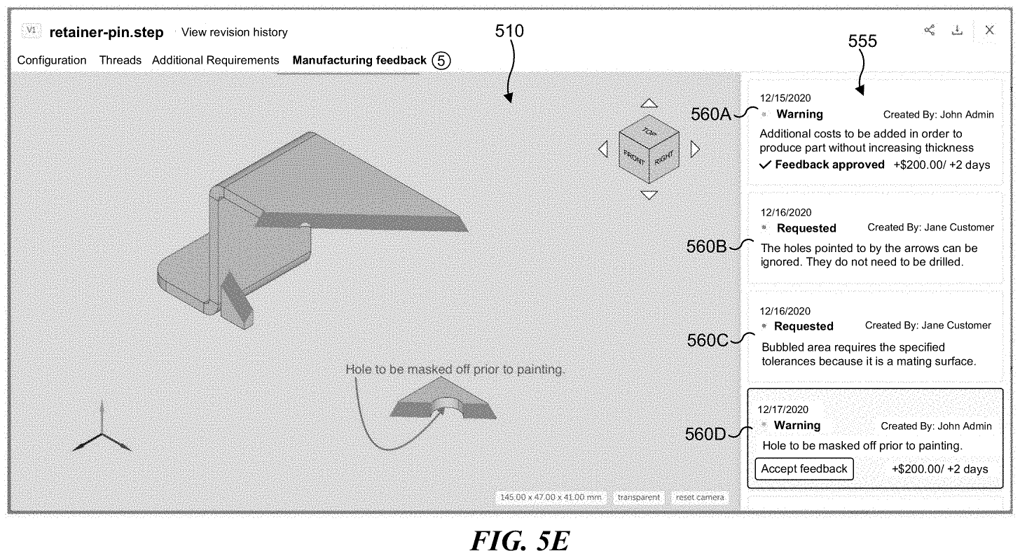

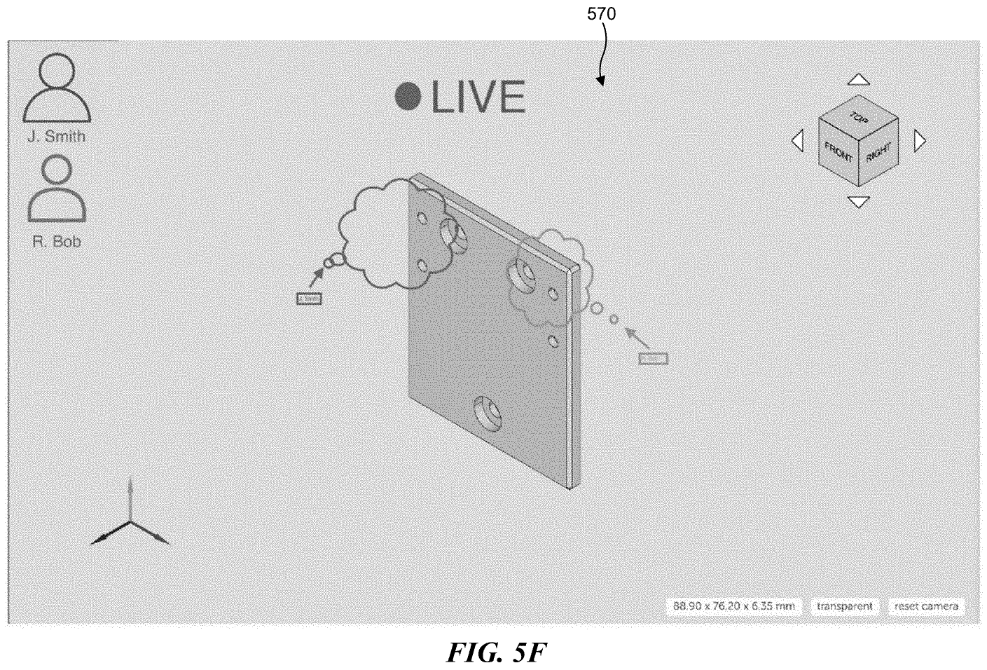

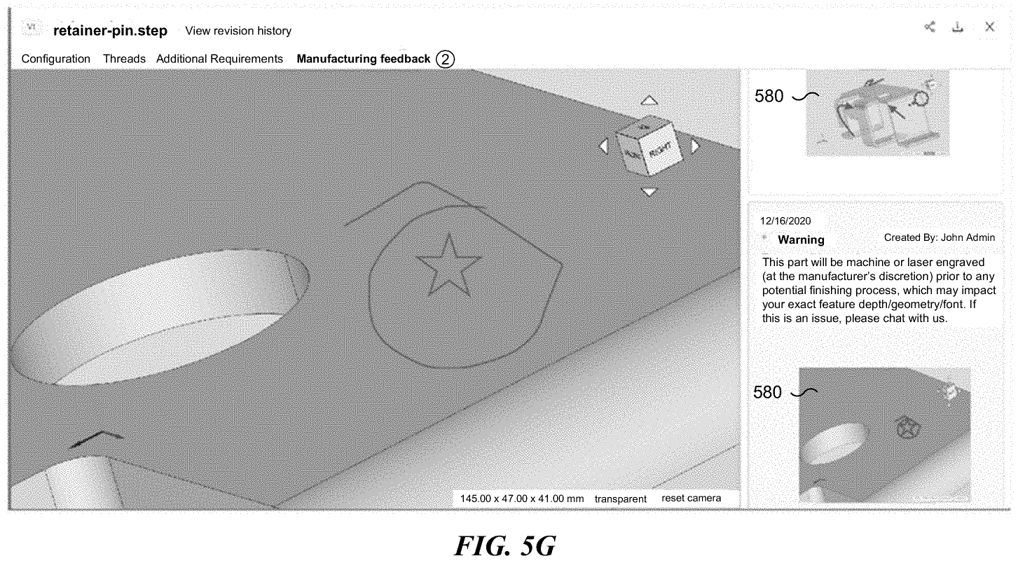

A reviewing user of the design analysis system 420 (referred to herein as a “reviewer”) can use the 3D viewer to review parts and leave manufacturability feedback or updates to the production parameters of the parts at block 446. FIG. 5A illustrates an example user interface generated by the design analysis system 420 and usable by the reviewer to annotate a design. As shown in FIG. 5A, the user interface can include a viewing region 510 that displays a rendered 3D model and any annotations added to the model. The reviewer can manipulate the rendered model within the viewing region 510 or by using other controls (not shown) to adjust the viewing mode of the model, rotate the model in three dimensions, zoom in or out of the model, or capture cross-sections of the rendered model. The reviewer can also request the design analysis system 420 perform automated debugging tasks (such as identifying features that are unreachable by a computer numerical control (CNC) machine). Furthermore, the user interface can include annotation controls that enable a user to create or edit annotations, by for example drawing freeform annotations, selecting from a set of predefined 2D or 3D shapes or arrows, adding a text box, or changing the color or texture of an annotation.

In the example shown in FIG. 5A, the reviewer has created an annotation that includes a freeform marking 512 to identify a section of the rendered model, a text box 514, and a comment 516 associated with the freeform marking and the text box. The comment 516 illustrates that the design analysis system 420 has updated the additional costs 517 and added lead time 519 caused by the design changes made by the annotation. The new costs and lead times can be manually input by the reviewer or can be calculated automatically by the design analysis system 420 based on the annotation. For example, if an annotation increases the thickness of a portion of the model, the design analysis system 420 recalculates the amount of material that will be used to produce the part and calculates the cost of the new amount of material. The comment 516 can further include a tag 521 to categorize the annotation. For example, annotations can be categorized with an “Issue” tag to indicate that the product cannot be manufactured unless a design change is made, or a “Warning” tag to indicate that the design is manufacturable but that an annotation may change the design or production parameters. The comment 516 can further include an identifier 523 of the user who created the annotation. Additional metadata other than that shown in FIG. 5A also can be associated with the annotation, such as time of creation of the annotation.

FIG. 5A additionally illustrates that the user interface includes controls 530 to create a new annotation. The user can select a tag 533 to apply to the annotation and enter a description in the text entry box 535. While creating the new annotation, the user can also manipulate the model in the viewing region 510 and draw shapes or text boxes directed to portions of the model. When the user has finished a set of annotations, the user selects the “Save” button 537 to cause the design analysis system 420 to capture the viewer state and store the new annotation in a database. When an annotation is accessed from the database, the annotation can include instructions that cause the 3D viewer to recreate the associated viewer state as the annotation is reviewed.

The customer will then be able to review the DFX feedback at block 448, including any additional increases of costs or lead times, changes to materials or dimensions, or other changes to the design file. FIG. 5B illustrates example annotations 540 displayed within the 3D viewer. When the customer selects one of the annotations 540, the viewer state at the time of the annotation's generation is recreated in the viewing region 510. Depending on the type of annotation, a user viewing the stored annotations can manipulate the 3D model and annotations to view them in varying states. A camera view of three- dimensional annotations, for example, can follow a camera view of the model as the model is manipulated. When a two-dimensional annotation is displayed on the 3D model, the annotation system may display the annotation while the model is within a threshold angle of the saved viewer state. If the user manipulates the model to rotate it beyond the threshold angle, the annotation is hidden until the user reactivates the saved state. In this case, other manipulations of the 3D model may be possible when a 2D annotation is displayed, such as zooming into or out of the displayed model or panning the camera in the plane of the annotation. Alternatively, some embodiments of the annotation system display the 2D annotation within a plane (e.g., by implementing the annotation as a texture map on a WebGL quad) that can rotate, pan, zoom, or otherwise follow manipulations of the 3D model.

If the customer approves the change implicated by the annotation, the customer can select an “Accept feedback” button 542. If the customer would prefer to upload a new model or chat with the reviewer about the annotations, the customer can select an “Upload revision” button 544 or a “Chat” button 546. When a new version of the model is uploaded, the design analysis system 420 can identify any differences between the previous version and the new version and display the differences on a rendered version of the model. For example, the design analysis system 420 can render modified components in different colors than unchanged components. In another example, the design analysis system 420 can render a translucent image of the previous version of a component on top of an opaque image of the current version to illustrate the differences between the previous and current versions.

FIG. 5C illustrates that the customer has approved the changes shown in FIG. 5B. Once the customer has approved the changes and the feedback, along with the associated increases and costs and lead times, and the approvals have been persisted in the database, the design analysis system 420 will be able to load these additional parameters and annotations from the database for any further purpose, such as to further update production parameters for the product.

Approved changes can be incorporated into a manufacturing drawing at block 450, which is a two-dimensional representation of the part which serves as the contract of the thing to be manufactured, often in PDF format. The design analysis system 420 can create a manufacturing drawing that reflects the annotations as seen in the 3D viewer, as shown for example in FIG. 5D, by capturing screenshots of various orientations or cross-sections of the object. The system creates the manufacturing drawing by retrieving the 3D model, as well as any associated geometric data, part configuration, DFX feedback, user requirements, or viewer annotations, from the database. The design analysis system 420 uses the geometric data to generate the different views from different perspectives and inserts those views onto one or more pages. During this process of manufacturing drawing generation, the system can then retrieve the approved annotations and reviewer or customer requirements or feedback, and use these along with any geometric data and other customer metadata in order to insert new view(s) into the manufacturing drawing.

In some implementations, the design analysis system 420 automatically incorporates into the manufacturing drawings at least some of the modifications that are specified by annotations. The design analysis system 420 can use any of a variety of techniques such as natural language processing, image processing, or analysis of geometric and topological features, to identify a feature within an annotated model and determine how the feature should be modified based on the annotation. In an example, an annotation includes a highlight of an edge on a 3D model and text indicating that the edge will be produced with a specified fillet size. The text of the annotation is processed (e.g., using natural language processing) to determine that a fillet should be applied to an edge and to extract the specified fillet size. The design analysis system 420 then uses image processing and geometric/topological analysis to identify the highlighted edge on the 3D model. When generating the manufacturing drawing, the design analysis system 420 can automatically modify the identified edge to show the specified fillet size. Text indicating the specified fillet size can also be added to the manufacturing drawing.

The manufacturing drawing can be stored in a cloud repository for later review by the customer, the reviewer, or the manufacturer. The initially uploaded CAD files as well as any automatically generated files such as the system generated manufacturing drawings and any converted files (such as files converted from native cad formats to standard CAD format) can be sent to the manufacturer to be used for the manufacturing of the parts or assemblies.

Should a customer choose to have a conversation with the reviewer about the feedback of their part, or leave special requirements of their own, they can similarly annotate the drawing in the 3D viewer. The stored annotations can be retrieved from the database and displayed in the 3D viewer. FIG. 5E illustrates an example interface displaying a set of annotations. In FIG. 5E, a log 555 is displayed with multiple annotation identifiers 560A-560D, along with timestamps indicating when each corresponding annotation was created, who created it, and other associated metadata such as comment severities. A user can select each annotation identifier 560 to view associated content. For example, when the annotation identifier 560D is selected, the viewer state associated with the annotation is re-created in the viewing region 510.

Annotations can be made in an asynchronous manner, where the reviewer, the customer, and/or the manufacturer access the drawing at different times to review each other's annotations or create their own annotations. In some implementations, the design analysis system 420 presents the annotations in separate layers that can each be toggled on or off to display, for example, annotations received from different users, annotations with different category labels, or annotations added since the user last reviewed the drawing. In other cases, annotations are made in a live environment where the customer, the reviewer, and/or the manufacturer are all viewing the 3D model at the same time, and in some cases can annotate simultaneously as well. For example, review can be performed on a live video call where one user shares a browser window containing the 3D viewer with the other users on the call. In another example, multiple users join a shared virtual space (e.g., an XR, VR, MR, or AR space) where each user can concurrently interact with and annotate the model. An example of a shared virtual space 570 is shown in FIG. 5E, where two users are concurrently viewing, manipulating, and annotating the same object.

In still other cases, annotations and DFX feedback are displayed as a slideshow either in the 3D viewer environment or exported to an external application, such as in a portable document format (PDF) or Microsoft Powerpoint presentation. An example portion of a slideshow is shown in FIG. 5G, which illustrates thumbnails 580 of the 3D viewer snapshots along with the annotation data. Within the slideshow, annotations can be sorted according to any of a variety of criteria, such as by ordering annotations in chronological order or reverse chronological order according to a time of creation, ordering annotations by category, or grouping annotations by creator. The viewer snapshots and screenshots can be automatically re-created by the system by loading data from a database and reconstructing the viewer state at the time of feedback creation.

### Example Processing System

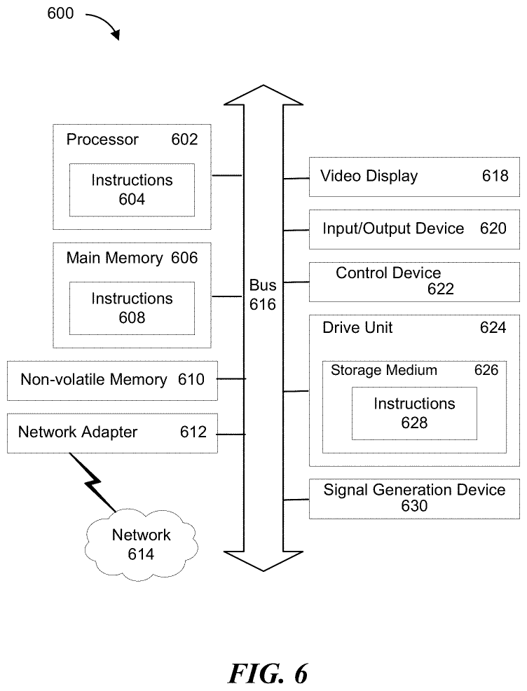

FIG. 6 is a block diagram illustrating an example of a processing system 600 in which at least some operations described herein can be implemented. For example, some components of the processing system 600 can be hosted on an electronic device as described in the present embodiments.

The processing system 600 can include one or more central processing units (“processors”) 602, main memory 606, non-volatile memory 610, network adapter 612 (e.g., network interface), video display 618, input/output devices 620, control device 622 (e.g., keyboard and pointing devices), drive unit 624 including a storage medium 626, and signal generation device 640 that are communicatively connected to a bus 616. The bus 616 is illustrated as an abstraction that represents one or more physical buses and/or point-to-point connections that are connected by appropriate bridges, adapters, or controllers. The bus 616, therefore, can include a system bus, a Peripheral Component Interconnect (PCI) bus or PCI-Express bus, a HyperTransport or industry standard architecture (ISA) bus, a small computer system interface (SCSI) bus, a universal serial bus (USB), IIC (I2C) bus, or an Institute of Electrical and Electronics Engineers (IEEE) standard 1394 bus (i.e., “Firewire”).

The processing system 600 can share a similar computer processor architecture as that of a desktop computer, tablet computer, personal digital assistant (PDA), smartphone, game console, music player, wearable electronic device (e.g., a watch or fitness tracker), network-connected (“smart”) device (e.g., a television or home assistant device), virtual/augmented reality systems (e.g., a head-mounted display), or another electronic device capable of executing a set of instructions (sequential or otherwise) that specify action(s) to be taken by the processing system 600.

While the main memory 606, non-volatile memory 610, and storage medium 626 (also called a “machine-readable medium”) are shown to be a single medium, the term “machine-readable medium” and “storage medium” should be taken to include a single medium or multiple media (e.g., a centralized/distributed database and/or associated caches and servers) that store one or more sets of instructions 628. The term “machine-readable medium” and “storage medium” shall also be taken to include any medium that is capable of storing, encoding, or carrying a set of instructions for execution by the processing system 600.

In general, the routines executed to implement the embodiments of the disclosure can be implemented as part of an operating system or a specific application, component, program, object, module, or sequence of instructions (collectively referred to as “computer programs”). The computer programs typically comprise one or more instructions (e.g., instructions 604, 608, 628) set at various times in various memory and storage devices in a computing device. When read and executed by the one or more processors 602, the instruction(s) cause the processing system 600 to perform operations to execute elements involving the various aspects of the disclosure.

Moreover, while embodiments have been described in the context of fully functioning computing devices, those skilled in the art will appreciate that the various embodiments are capable of being distributed as a program product in a variety of forms. The disclosure applies regardless of the particular type of machine or computer-readable media used to actually effect the distribution.

Further examples of machine-readable storage media, machine-readable media, or computer-readable media include recordable-type media such as volatile and non- volatile memory devices 610, floppy and other removable disks, hard disk drives, optical disks (e.g., Compact Disk Read-Only Memory (CD-ROMS), Digital Versatile Disks (DVDs)), and transmission-type media such as digital and analog communication links.

The network adapter 612 enables the processing system 600 to mediate data in a network 614 with an entity that is external to the processing system 600 through any communication protocol supported by the processing system 600 and the external entity. The network adapter 612 can include a network adaptor card, a wireless network interface card, a router, an access point, a wireless router, a switch, a multilayer switch, a protocol converter, a gateway, a bridge, bridge router, a hub, a digital media receiver, and/or a repeater.

The network adapter 612 can include a firewall that governs and/or manages permission to access/proxy data in a computer network and tracks varying levels of trust between different machines and/or applications. The firewall can be any number of modules having any combination of hardware and/or software components able to enforce a predetermined set of access rights between a particular set of machines and applications, machines and machines, and/or applications and applications (e.g., to regulate the flow of traffic and resource sharing between these entities). The firewall can additionally manage and/or have access to an access control list that details permissions including the access and operation rights of an object by an individual, a machine, and/or an application, and the circumstances under which the permission rights stand.

The techniques introduced here can be implemented by programmable circuitry (e.g., one or more microprocessors), software and/or firmware, special-purpose hardwired (i.e., non-programmable) circuitry, or a combination of such forms. Special-purpose circuitry can be in the form of one or more application-specific integrated circuits (ASICs), programmable logic devices (PLDs), field-programmable gate arrays (FPGAs), etc.

The techniques disclosed herein can include a tool or system to extract information from a design drawing to supplement the capabilities of a product manufacturing process. The present embodiments can assist in the generation/modification of a quote/estimate, the generation of manufacture feedback, the manufacturing scheduling/ordering process, etc.

### Remarks

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or” in reference to a list of two or more items covers all of the following interpretations of the word: any of the items in the list, all of the items in the list, and any combination of the items in the list.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

The above Detailed Description of examples of the invention is not intended to be exhaustive or to limit the invention to the precise form disclosed above. While specific examples for the invention are described above for illustrative purposes, various equivalent modifications are possible within the scope of the invention, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the invention provided herein can be applied to other systems, not necessarily the system described above. The elements and acts of the various examples described above can be combined to provide further implementations of the invention. Some alternative implementations of the invention may include not only additional elements to those implementations noted above, but also may include fewer elements.

These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated.

We claim:

1. A system comprising:
at least one processor; and
at least one non-transitory memory storing instructions, which, when executed by the at least one processor, cause the system to:
retrieve a set of annotations associated with a computer-aided design (CAD) file,
wherein the CAD file includes rendering instructions readable by the system to render an object in a graphics viewer, and
wherein each annotation in the set has associated annotation data directed to a modification to at least one parameter of the object and associated viewer state data that defines a state of the rendered object in the graphics viewer at a time the corresponding annotation data was created;
display a first annotation from the set of annotations in the graphics viewer by
a) displaying the annotation data associated with the first annotation and
b) rendering the object in the graphics viewer according to the viewer state data associated with the first annotation;
in response to a user input to display a second annotation from the set of annotations, display the second annotation by displaying the annotation data associated with the second annotation and modifying the rendering of the object in the graphics viewer in order to render the object according to the viewer state data associated with the second annotation; and
in response to receiving approval of one or more of the annotations in the set of annotations, generate manufacturing instructions for manufacture of the object based on the CAD file and the one or more approved annotations.

2. At least one computer-readable storage medium, excluding transitory signals and carrying instructions, which, when executed by at least one data processor of a system, cause the system to:
access a set of annotations associated with a computer-aided design (CAD) file,
wherein the CAD file includes rendering instructions readable by the system to render an object in a graphics viewer, and
wherein each annotation in the set has associated annotation data directed to a modification to at least one parameter of the object and associated viewer state data that defines a state of the rendered object in the graphics viewer at a time the corresponding annotation data was created;
display a first annotation from the set of annotations in the graphics viewer by:
displaying the annotation data associated with the first annotation, and
rendering the object in the graphics viewer according to the viewer state data associated with the first annotation; and
in response to a user input to display a second annotation from the set of annotations, display the second annotation by displaying the annotation data associated with the second annotation and modifying the rendering of the object in the graphics viewer in order to render the object according to the viewer state associated with the second annotation.

3. The at least one computer-readable storage medium of claim 2, wherein the instructions when executed further cause the system to:
manipulate the object within the graphics viewer to a specified viewer state in response to a manipulation input received from a user;
in response to an annotation input received from the user within the graphics viewer, define a new annotation directed to the rendered object, the new annotation including new annotation data specifying a corresponding modification to at least one parameter of the object; and
store the new annotation data in association with an identifier of the specified viewer state.

4. The at least one computer-readable storage medium of claim 3, wherein the instructions when executed further cause the system to display the graphics viewer in a shared virtual space concurrently accessed by multiple users, and wherein the user is one of the multiple users.

5. The at least one computer-readable storage medium of claim 4, wherein the instructions when executed further cause the system to:
calculate a first price to manufacture the product based on the CAD file; and
in response to defining the new annotation:
automatically calculate a second price to manufacture the product based on the new annotation; and
display the second price in the shared virtual space while the shared virtual space is concurrently accessed by the multiple users.

6. The at least one computer-readable storage medium of claim 4, wherein the instructions when executed further cause the system to:
calculate a first lead time to manufacture the product based on the CAD file; and
in response to defining the new annotation:
automatically calculate a second lead time to manufacture the product based on the new annotation; and
display the second lead time in the shared virtual space while the shared virtual space is concurrently accessed by the multiple users.

7. The at least one computer-readable storage medium of claim 2, wherein annotations in the set of annotations were created by a first user during a first user session, and wherein displaying the first annotation comprises displaying the first annotation to a second user during a second user session that is asynchronous from the first user session.

8. The at least one computer-readable storage medium of claim 2, wherein the annotation data associated with the first annotation includes a shape displayed at a position relative to the object when rendered according to the viewer state data associated with the first annotation.

9. The at least one computer-readable storage medium of claim 8, wherein the instructions when executed further cause the system to:
in response to a user input to manipulate a view of the object, maintain the position of the shape relative to the object during the manipulation.

10. The at least one computer-readable storage medium of claim 2, wherein each annotation in the set of annotations is further associated with an identifier of a user who created the annotation and a timestamp identifying a time the annotation was made, and wherein the instructions when executed further cause the system to generate a change log for the object based on the set of annotations.

11. The at least one computer-readable storage medium of claim 2, wherein the set of annotations is associated with a first version of the CAD file, and the instructions when executed further cause the system to:
receive a second version of the CAD file;
compare the first version of the CAD file with the second version of the CAD file to identify a change made to at least one component of the object in the second version of the CAD file; and
while rendering the object using the second version of the CAD file, display the at least one component of the object so as to identify the change.

12. The at least one computer-readable storage medium of claim 2, wherein the instructions when executed further cause the system to generate manufacturing instructions for manufacturing the object based on the CAD file and the set of annotations.

13. At least one computer-readable storage medium, excluding transitory signals and carrying instructions, which, when executed by at least one data processor of a system, cause the system to:
receive a computer-aided design (CAD) file that includes rendering instructions readable by the system to render an object in a graphics viewer;
capture an annotation directed to the rendered object based on a user input received at the graphics viewer, the annotation specifying a modification to at least one parameter of the object; and
generate manufacturing instructions for manufacturing of the object based on the CAD file and the annotation.

14. The at least one computer-readable storage medium of claim 13, wherein generating the manufacturing instructions comprises changing at least one dimension of the object.

15. The at least one computer-readable storage medium of claim 13, wherein generating the manufacturing instructions comprises changing at least one material used to manufacture the object.

16. The at least one computer-readable storage medium of claim 13, wherein the instructions when executed further cause the system to calculate an initial price to manufacture the object based on the CAD file, and wherein generating the manufacturing instructions comprises calculating a modified price to manufacture the object based on the modification to the at least one parameter of the object.

17. The at least one computer-readable storage medium of claim 13, wherein the instructions when executed further cause the system to calculate an initial lead time to manufacture the object based on the CAD file, and wherein generating the manufacturing instructions comprises calculating a modified lead time to manufacture the object based on the modification to the at least one parameter of the object.

18. The at least one computer-readable storage medium of claim 13, wherein the rendering instructions are readable by the system to render the object in three dimensions in the graphics viewer and display the annotation in association with the three-dimensional rendered object.

19. The at least one computer-readable storage medium of claim 18, wherein the annotation includes a shape displayed at a position relative to the three-dimensional rendered object, and wherein the instructions when executed further cause the system to:
in response to a user input to manipulate a view of the three-dimensional rendered object, maintain the position of the shape relative to the object during the manipulation.

20. The at least one computer-readable storage medium of claim 13, wherein the instructions when executed further cause the system to display the graphics viewer in a shared virtual space concurrently accessed by multiple users, and wherein the annotation is captured while the multiple users concurrently access the shared virtual space.
